(19) United States
(12) Patent Application Publication
(10) Pub. No.: US 2025/0060631 A1
(43) Pub. Date: Feb. 20, 2025

(54) DISPLAYS WITH EXPANDED GAMUT COVERAGE AND LOW BLUE LIGHT EMISSION

(71) Applicant: GE Intellectual Property Licensing, LLC, Niskayuna, NY (US)

(72) Inventors: Samuel Joseph Camardello, Ballston Spa, NY (US); James Edward Murphy, Niskayuna, NY (US)

(21) Appl. No.: 18/939,878

(22) Filed: Nov. 7, 2024

Related U.S. Application Data
(63) Continuation of application No. 17/783,626, filed on Jun. 8, 2022.
(60) Provisional application No. 62/945,830, filed on Dec. 9, 2019.

(51) Int. Cl. G02F 1/1335; B82Y 20/00; C09K 11/04; C09K 11/61; C09K 11/77; F21V 8/00; G02F 1/13357; H01L 33/50

(52) U.S. Cl. CPC G02F 1/133614; C09K 11/04; C09K 11/617; C09K 11/77348; G02B 6/0068; G02B 6/0073; G02F 1/133514; G02F 1/133603; G02F 1/133609; H01L 33/502; B82Y 20/00; G02F 2201/52; G02F 2202/36

(57) ABSTRACT

A display including a red subpixel, a green subpixel, a blue subpixel and a fourth subpixel including a teal subpixel or a saturated green pixel and an LED light source. Liquid crystal display devices including U⁶⁺-containing phosphors are also provided. Applications for the display include televisions, mobile phones and computer monitors.

### CROSS-REFERENCE TO RELATED APPLICATION

This application is a continuation of U.S. patent application Ser. No. 17/783,626, filed Jun. 8, 2022, which is a national phase of International Patent Application No. PCT/US2020/063925 filed Dec. 9, 2020, which claims the priority benefit of Application Ser. No. 62/945,830 filed Dec. 9, 2019, the entireties of which are incorporated by reference.

### BACKGROUND

The subject matter described herein relates generally to displays and more particularly, to color displays with expanded gamut coverage and reduced blue light emission.

Many display devices or displays, such as televisions, personal computers and desktop computer monitors use liquid crystal display (LCD) panels and light emitting diode (LED) backlight units (BLU) to provide white light for the display devices. LEDs are a display technology using a pn-junction diode to emit light when activated through electroluminence. LED backlight units can be based on a combination of a blue LED and green and red phosphors. The white light from the LED BLU is directed toward the LCD panel. To produce color images or a color display, the LCD panel typically, uses a three color filter, to emit light in the ranges for the three primary colors red, green and blue (collectively referred to as RGB or RGB filter).

Standards for display devices continue to push to higher gamut. The UHD alliance (ultra high definition) standards for ultra high definition television (UHDTV) require displays to accept inputs for REC2020 color gamut, but to be certified the display must only be able to reproduce 90% or more of the DCI-P3 color. Many displays are currently unable to reproduce the stringent REC2020 requirements.

It is well known that long-term exposure to ultraviolet (UV) light disrupts circadian rhythm and can cause damage to human skin and eyes, particularly, eyes are of concern for near eye displays, such as computer monitors, phones and AR/VR displays. The 2020 Guidelines from Eyesafe® Standard for Display Devices dated Aug. 1, 2020 require that the ratio of light in the range from 415-455 nm compared to light in the range of 400-500 nm must be less than 50%.

In order to reduce blue light, current solutions on the market shift the color point of the screen to a warmer white color point, but reduction of blue light alone offsets the RGB ratio and impacts the display image quality output. For example, shifting the color point of the screen to a warmer white color point, makes the screen look yellow/red and leads to a lower overall color gamut.

### BRIEF DESCRIPTION

In one aspect, a display is provided. The display includes a red subpixel, a green subpixel, a blue subpixel and a fourth subpixel comprising a teal subpixel or a saturated green subpixel and an LED light source.

In another aspect, a display device for producing a color image is provided. The display device comprises an LED backlight unit, a liquid crystal display panel and a pixel including four subpixels including a red subpixel, a green subpixel, a blue subpixel and a teal subpixel or a saturated green subpixel. The LED backlight unit includes a combination of a blue LED optically coupled to a U⁶⁺-containing phosphor and a red phosphor.

### DRAWINGS

These and other features, aspects, and advantages of the present disclosure will become better understood when the following detailed description is read with reference to the accompanying drawings in which like characters represent like parts throughout the drawings, wherein:

FIG. 1A is a transmission graph for blue and green pigment dyes in a color filter. The graph shows relative transmission versus wavelength (nm).

FIG. 1B is a transmission graph for a teal color filter from the blue and green overlap in FIG. 1A. The graph shows relative transmission versus wavelength (nm).

FIG. 2 is a schematic of a light emitting diode backlight unit in accordance with one aspect of the disclosure.

FIG. 3 is a schematic cross-sectional view of a lighting apparatus in accordance with an aspect of the disclosure.

FIG. 4 is a schematic cross-sectional view of a lighting apparatus, in accordance with another aspect of the disclosure.

FIG. 5 is a schematic cross-sectional view of a lighting apparatus, in accordance with another aspect of the disclosure.

FIG. 6 is a schematic perspective view of a backlight apparatus, in accordance with an aspect of the disclosure.

FIG. 7A illustrates a liquid crystal display (LCD) with an edge lit backlight configuration.

FIG. 7B illustrates a liquid crystal display (LCD) with a direct lit backlight configuration.

FIG. 8 illustrates a backlight unit or module according to the present disclosure.

FIG. 9A is color space graphed in (ccx,ccy) showing color gamut for an aspect of the disclosure, comparative example and color standards.

FIG. 9B is color space graphed in (u′,v′) showing color gamut for an aspect of the disclosure, comparative example and color standards.

FIG. 10A is color space graphed in (ccx,ccy) showing color gamut for a comparative example and color standards.

FIG. 10B is color space graphed in (u′,v′) showing color gamut for a comparative example and color standards.

FIG. 11A is color space graphed (ccx,ccy) showing color gamut for an aspect of the disclosure and color standards.

FIG. 11B is color space graphed in (u′,v′) showing color gamut for an aspect of the disclosure and color standards.

FIG. 12A is color space graphed in (ccx,ccy) showing color gamut for an aspect of the disclosure, comparative example and color standards.

FIG. 12B is color space graphed in (u′,v′) showing color gamut for an aspect of the disclosure, comparative example and color standards.

FIG. 13A is color space graphed in (ccx,ccy) showing color gamut for an aspect of the disclosure and color standards.

FIG. 13B is color space graphed in (u′,v′) showing color gamut for an aspect of the disclosure and color standards.

FIG. 14 is an emission spectra for exemplary U⁶⁺-containing phosphors. The graph shows relative intensity versus wavelength (nm).

FIG. 15A is color space graphed in (ccx,ccy) showing color gamut for an aspect of the disclosure and color standards.

FIG. 15B is color space graphed in (u′,v′) showing color gamut for an aspect of the disclosure and color standards.

FIG. 15C is color space graphed in (ccx,ccy) showing color gamut for an aspect of the disclosure and color standards.

FIG. 15D is color space graphed in (u′,v′) showing color gamut for an aspect of the disclosure and color standards.

FIG. 15E is color space graphed in (ccx,ccy) showing color gamut for an aspect of the disclosure and color standards.

FIG. 15F is color space graphed in (u′,v′) showing color gamut for an aspect of the disclosure and color standards.

FIG. 16A shows emission spectra of varying blue to green pigment ratio in a teal filter. The graph is relative intensity vs. wavelength (nm).

FIG. 16B is color space graphed in (ccx,ccy) based on the blue to green ratios in FIG. 16A.

FIG. 16C is color space graphed in (u′,v′) based on the blue to green ratios in FIG. 16A.

Unless otherwise indicated, the drawings provided herein are meant to illustrate features of embodiments of the disclosure. These features are believed to be applicable in a wide variety of systems comprising one or more embodiments of the disclosure. As such, the drawings are not meant to include all conventional features known by those of ordinary skill in the art to be required for the practice of the embodiments disclosed herein.

### DETAILED DESCRIPTION

In the following specification and the claims, reference will be made to a number of terms, which shall be defined to have the following meanings.

The singular forms “a”, “an” and “the” include plural references unless the context clearly dictates otherwise. References to “one embodiment” or “one aspect” are not intended to be interpreted as excluding the existence of additional embodiments or aspects that also incorporate the recited features. All references are incorporated herein by reference.

Approximating language, as used herein throughout the specification and claims, may be applied to modify any quantitative representation that could permissibly vary without resulting in a change in the basic function to which it is related. Accordingly, a value modified by a term or terms, such as “about,” “substantially,” and “approximately,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

“Optional” or “optionally” means that the subsequently described event or circumstance may or may not occur, or that the subsequently identified material may or may not be present, and that the description includes instances where the event or circumstance occurs or where the material is present, and instances where the event or circumstance does not occur or the material is not present.

Square brackets in the formulas indicate that at least one of the elements is present in the phosphor composition, and any combination of two or more thereof may be present. For example, the formula [Ca,Sr,Ba]₃MgSi₂O₈:Eu²⁺,Mn²⁺ encompasses at least one of Ca, Sr or Ba or any combination of two or more of Ca, Sr or Ba. Examples include Ca₃MgSi₂O₈:Eu²⁺·Mn²⁺, Sr₃MgSi₂O₈:Eu²⁺·Mn²⁺ or Ba₃MgSi₂O₈:Eu²⁺·Mn²⁺. Formula with an activator after a colon “:” indicates that the phosphor composition is doped with the activator. Formula showing more than one activator separated by a “,” after a colon “:” indicates that the phosphor composition is doped with either activator or both activators. For example, the formula [Ca,Sr,Ba]₃MgSi₂O₈:Eu²⁺,Mn²⁺ encompasses [Ca,Sr,Ba]₃MgSi₂O₈:Eu²⁺, [Ca,Sr,Ba]₃MgSi₂O₈:Mn²⁺ or [Ca,Sr,Ba]₃MgSi₂O₈:Eu²⁺ and Mn²⁺.

In one aspect, a display is provided. The display includes a red subpixel, a green subpixel, a blue subpixel and a fourth subpixel comprising a teal subpixel or a saturated green subpixel and an LED light source.

A display device or display provides information or images from a processor or other type of information management system by converting electrical signals into pixilated multicolor displays. One type of display may be LED (light emitting diode) displays with an array of pixels. Displays may be self-emissive, such as micro-LED or organic light emitting diode displays (OLED) with organic light emitting diode layers to produce light. A liquid crystal display (LCD) uses backlighting, such as from LED light sources and individual liquid crystal cells. Display applications include, but are not limited to televisions, plasma screens, home and theater projections, digital photo frames, tablets, automotive displays, e-book reader, electronic dictionary, digital camera, computers, laptops, computer monitors, electronic keyboard, cellular or conventional phone, mobile phones, smartphones, tablet computers, gaming device, other handheld devices that have a display and other electronic devices with a screen. The list of these applications is meant to be merely exemplary and not exhaustive.

In one aspect, the display device comprises four color direct converting RGBT LEDs. In another aspect, the display device may be near the eye, such as an AR/VR application.

In one aspect, the LED light source is a light emitting diode. In one embodiment, the LED light source may be micro LEDs or miniLEDs with color conversion, In one aspect, the LED light source may include an organic light emitting diode (OLED), an array of micro blue LEDs, micro red LEDS, micro green LEDs and micro teal LEDs or micro saturated green LEDs, semiconductor laser diodes (LD) or a hybrid of an LED and LD. Further, it should be understood that the LED light source may be replaced, supplemented or augmented by another radiation source, unless otherwise noted, and that any reference to semiconductor, semiconductor LED or LED chip is merely representative of any appropriate radiation source, including, but not limited to LDs and OLEDs.

In one aspect, the pixel includes four subpixels including a red subpixel, a green subpixel, a blue subpixel and a teal subpixel or a saturated green subpixel. The pixels may be created by direct emission or with a color filter. In one aspect, the pixel may by generated by a blue micro-LED, red micro-LED, green micro-LED and a teal micro-LED or saturated green micro-LED. In another aspect, the pixel may be generated by a four color filter including a red filter, a green filter, a blue filter and a teal filter or saturated green filter.

In one embodiment, a red color filter allows emission in the red spectrum. In another embodiment, the red color filter transmits light with wavelengths of 590 nm and longer. In one aspect, the blue color filter pigment transmits in the range of about 390 nm to about 500 nm and the green color filter pigment transmits in the range of about 460 nm to about 620 nm.

In one aspect, the four color filter 122 has a glass substrate and coloring materials or color resist for each of the four pixels. In one embodiment, the color filter has a red color resist, a green color resist, a blue color resist and either a teal color resist or a saturated green color resist. Conventional color filters and filter pigments and other color materials may be used to prepare or obtain a color filter comprising a red subpixel section, a green subpixel section, a blue subpixel section and a teal subpixel section or a saturated green subpixel section.

The term teal includes cyan, turquoise, electric blue, aquamarine, and other blue-green colors. A teal subpixel may be produced by applying a teal color filter or teal LED. The teal color filter or teal LED has an emission in the range of from about 460 nm to about 550 nm. In another aspect, the emission is in the range of about 470 nm to about 525 nm. In another embodiment, the emission is in the range from about 480 nm to about 510 nm. A teal subpixel or cyan subpixel may be made by blending the blue and green color filter pigments together and forming the fourth subpixel section in the area of overlap between the blue and green pigments. In one aspect, the blue color filter pigment transmits in the range of about 390 nm to about 500 nm and the green color filter pigment transmits in the range of about 460 nm to about 620 nm and the overlap area between these pigments is in a range of from about 460 nm to about 550 nm.

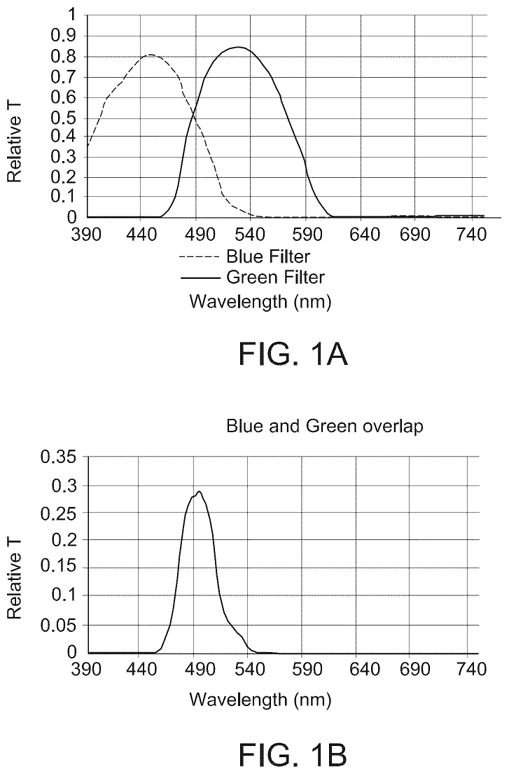

FIG. 1A provides a spectral transmission graph showing the wavelength ranges for a blue color filter pigment and a green color filter pigment. The area of overlap between the blue and green pigments defines the teal or cyan color subpixel shown in FIG. 1B showing a transmission in the range of from about 460 nm to about 550 nm. In one aspect, the color point of the teal subpixel may be obtained by a four color RGBT filter. The teal color may be changed by varying the blue to green ratio. In one embodiment, a teal subpixel may vary ratios of blue to green in an amount of from about 1:3 to about 3:1. In another embodiment, the ratio of blue to green may be in an amount of from about 1:2 to about 2:1. In another embodiment, the ratio of blue to green may be in an amount of 1:1. These are meant to be examples of the blend ratios to produce a teal subpixel, but the ratio and optical density of the teal color filter can be changed to optimize the overall display.

A saturated green subpixel may be produced by applying a saturated green color filter or saturated green LED. The saturated green color filter or saturated green LED has an emission in the range of from about 505 nm to about 525 nm. In another embodiment, the emission may be in a range of from about 510 nm to about 525 nm. A saturated green color filter may be made by blending blue and green color filter pigments together.

In one aspect of the present disclosure, a display device is provided. The display device comprises a light emitting diode (LED) backlight unit (BLU), a liquid crystal display (LCD) panel and a pixel including a red subpixel, a green subpixel, a blue subpixel and a teal subpixel or a saturated green subpixel. The LED backlight unit includes a combination of a blue LED optically coupled to a U⁶⁺-containing phosphor and a red phosphor.

The display or display device comprises an LCD panel, which is configured to display color images. The LCD panel is unable to radiate light itself and uses an LED backlight unit to provide a white backlight to pass through the LCD panel. The LED uses a pn-junction diode to emit light when activated through electroluminescence. The color of the light corresponds to the energy of the photon in accordance with the energy band gap of the semiconductor materials.

The LED backlight unit includes a combination of a blue LED optically coupled to a U⁶⁺-containing phosphor and a red phosphor. The LED emits blue light and the red phosphor and U⁶⁺-containing phosphor absorb a portion of the emitted blue light and emit red and green light, respectively. The light emitted from the red phosphor and the green phosphor mix with light emitted from the blue LED and produce a white light, which is passed through the LCD panel and a four color RGBT or RGGB filter to generate a color display image.

In one aspect, the blue LED may be a blue emitting LED semiconductor diode based on a nitride compound semiconductor of formula InᵢGaⱼAlₖN (where 0<i; 0<j; 0<k and i+j+k=1) or blue emitting GaInN chips. In one aspect, the blue LED emits blue light with a peak wavelength ranging from about 400 to about 500 nm. In another aspect, the blue LED has a peak emission wavelength from about 440 to about 460 nm. In another aspect, the blue LED has a peak emission wavelength from about 450 to about 465 nm. In another aspect, the blue LED emits blue light with a peak wavelength of about 444 nm. In another aspect, the BLU comprises a plurality of LEDs.

In one aspect, the green-emitting U⁶⁺-containing phosphors absorb radiation in the near-UV or blue region (a wavelength range between about 400 nm and 470 nm). The U⁶⁺ ion can emit in wavelengths covering the whole visible spectrum. Depending on the coordination of the U⁶⁺ ion and the host lattice, the phosphor may emit in the green range (490 nm to 560 nm) as a broad band with an FWHM of 40 nm to 65 nm or as multiple peaks in the green range (490 nm to 560 nm). In one embodiment, the phosphor has a line emission composed of five peaks with each peak having a FWHM of 2 nm to 15 nm. In one embodiment, a line emission may range from about 470 nm to about 505 nm. In another embodiment, the line emission is in a range from about 480 nm to about 500 nm. In another embodiment, a line emission may be in a range from about 485 nm to about 505 nm. In another embodiment, a line emission may be in a range from about 490 nm to about 500 nm. In another embodiment, a line emission may be in a range from about 495 nm to about 500 nm. In another embodiment, the U⁶⁺-containing phosphor has a line emission in a wavelength range from about 505 nm to about 530 nm. In another embodiment, the line emission may be in a range from about 510 nm to about 530 nm. In another embodiment, the line emission may be in a range from about 515 nm to about 525 nm. In another embodiment, the line emission may be in a range from about 518 nm to about 525 nm. In another aspect, the line emission may be in a range from about 520 nm to about 525 nm. In another aspect, the U⁶⁺-containing phosphor emits as a distinct line with full width at half maximum (FWHM) of 5 nm or less. In another aspect, the U⁶⁺-containing phosphor emits as a distinct line with FWHM from about 2 nm to about 5 nm. In another aspect, the U⁶⁺-containing phosphor emits as a distinct line with FWHM at about 2 nm. The green-emitting U⁶⁺-containing phosphors may contain U⁶⁺ within the host of the phosphor compound or may be activated or doped with an activator ion U⁶⁺. In one aspect, the U⁶⁺-containing phosphor is a U⁶⁺-containing phosphor having the characteristic line emission spectra of U⁶⁺. In another aspect, the U⁶⁺-containing phosphor includes BaZn₂(PO₄)₂:U⁶⁺, BaBPO₅:U⁶⁺, K₃UO₂F₅, K₂(UO₂)(SO₄)₂₋ 2H₂O, Cs₂(UO₂)₂(SO₄)₃, BaZnUO₂(PO₄)₂, BaMgUO₂(PO₄)₂, Ba₃(PO₄)₂(UO₂)₂P₂O₇ or Sr₃P₄O₁₃:U⁶⁺.

Phosphor compounds BaBPO₅:U⁶⁺ and Sr₃P₄O₁₃:U⁶⁺ are described in U.S. Published Application No. US2019/0088827.BaZnUO₂(PO₄)₂ can be prepared by combining stoichiometric amounts of BaCO₃, ZnO, UO₂ and (NH₄)₂HPO₄ (DAP) and thoroughly blending the mixture to form a powder and firing the blend at at 500° C. to decompose the DAP and at 1000-1100° C. to produce the composition. BaMgUO₂(PO₄)₂ can be prepared in a similar manner by combining stoichiometric amounts of BaCO₃, MgO, UO₂ and (NH₄)₂HPO₄ (DAP). Ba₃(PO₄)₂(UO₂)₂P₂O₇ can be prepared in a similar manner by combining stoichiometric amounts of BaCO₃, UO₂ and (NH₄)₂HPO₄ (DAP).

The green-emitting U⁶⁺-containing phosphors may be used with additional green phosphors. Any suitable green-emitting phosphor may be used. Examples of green phosphors are disclosed in U.S. Publication No. 2019/008827, the entire contents of which are hereby incorporated by reference.

In one aspect, additional green phosphors may emit in a broad band of FWHM from 25 nm to 60 nm. In another aspect, additional green phosphors may be cerium-doped yttrium aluminum garnet, Ce:YAG, or P—SiAlON:Eu²⁺. In another aspect, additional green-emitting U⁶⁺-doped phosphor may include: Sr₃B₂O₆:U⁶⁺, Ca₃B₂O₆:U⁶⁺, Ca₁₀P₆O₂₅:U⁶⁺, Sr₁₀P₆O₂₅:U⁶⁺, Sr₄AlPO₈:U⁶⁺, Ba₄AlPO₈:U⁶⁺, Sr₂SiO₄:U⁶⁺, Ca₂SiO₄:U⁶⁺, Sr₃Al₂O₆:U⁶⁺, Ca₃Al₂O₆:U⁶⁺, Ca₁₂Al₁₄O₃₃:U⁶⁺, Ca₂Al₂SiO₇:U⁶⁺, Ca₂BO₃Cl:U⁶⁺, Ca₂PO₄Cl:U⁶⁺, Ca₅(PO₄)₃Cl:U⁶⁺, Sr₅(BO₃)₃Cl:U⁶⁺, Ca₂GeO₄:U⁶⁺, Sr₂GeO₄:U⁶⁺, Ca₃V₂O₈:U⁶⁺, NaCaPO₄:U⁶⁺, Ca₃In₂O₆:U⁶⁺, LiSrBO₃:U⁶⁺, LiCaBO₃:U⁶⁺, Sr₃Ga₂O₆:U⁶⁺ and LiSr₄B₃O₉:U⁶⁺ green silicates and green sulfides.

In one aspect, the red phosphor may be a high gamut phosphor. In one aspect, the red-emitting phosphors may include a Mn⁴⁺-doped complex fluoride phosphor. In one aspect, the Mn⁴⁺-doped phosphor has formula I: A₂(MF₆):Mn⁴⁺, wherein A is Li, Na, K, Rb, Cs or a combination thereof; M is Si, Ge, Sn, Ti, Zr, Al, Ga, In, Sc, Hf, Y, La, Nb, Ta, Bi, Gd, or a combination thereof. Some examples of Mn⁴⁺-doped phosphors include, but are not limited to: K₂(SiF₆):Mn⁴⁺, Na₂SiF₆:Mn⁴⁺, K₂(TiF₆):Mn⁴⁺, K₂(SnF₆):Mn⁴⁺, Cs₂(TiF₆):Mn⁴⁺, Rb₂(TiF₆):Mn⁴⁺, Cs₂(SiF₆):Mn⁴⁺, Rb₂(SiF₆):Mn⁴⁺, Na₂(TiF₆):Mn⁴⁺, Na₂(ZrF₆):Mn⁴⁺, K₃(ZrF₇):Mn⁴⁺, K₃(BiF₇):Mn⁴⁺, K₃(YF₇):Mn⁴⁺, K₃(LaF₇):Mn⁴⁺, K₃(GdF₇):Mn⁴⁺, K₃(NbF₇):Mn⁴⁺ and K₃(TaF₇):Mn⁴⁺. In one aspect, the red phosphor is a manganese-doped potassium fluorosilicate (PFS). In another embodiment, the red phosphor may be K₂SiF₆:Mn⁴⁺. In another aspect, the red phosphor may be europium-activated yttrium oxide phosphor (Y₂O₃:Eu³⁺; YOE), europium-activated yttrium vanadate-phosphate (Y[P,V]O₄:Eu) or cerium and manganese-activated gadolinium (CBM), MFG, red SiAlON and red nitride.

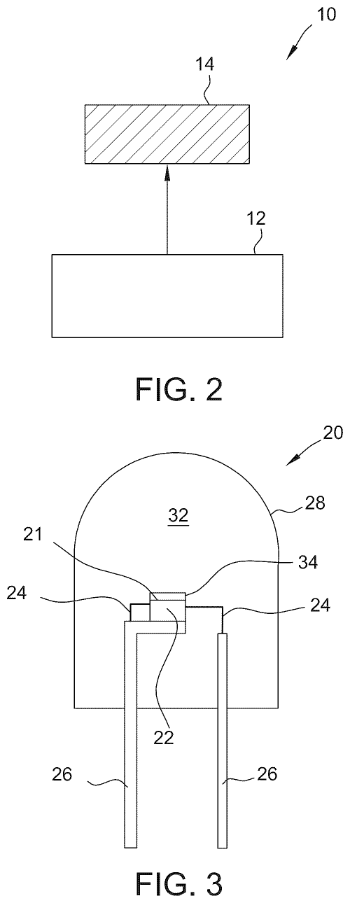

FIG. 2 shows an exemplary embodiment of an LED backlight unit 10 or device. The LED backlight unit 10 includes an LED light source 12 and a phosphor material 14 including a U⁶⁺-containing phosphor and a red phosphor. The LED light source 12 may comprise a blue-emitting LED. In some embodiments, the LED light source 12 produces blue light in a wavelength range from about 440 nm to about 460 nm. In the LED backlight unit 10, the phosphor material 14 including the U⁶⁺-containing phosphor and red phosphor is optically coupled to the LED light source 12. Optically coupled means that radiation from the LED light source 12 is able to excite the phosphor material 14, and the phosphor material 14 is able to emit light in response to the excitation by the radiation. The phosphor material 14 may be disposed on at least a part or portion of the LED light source 12 or located remotely at a distance from the LED light source 12. A backlight unit and related devices are described in U.S. Patent Application Publication No. US2017/0254943 A1.

The phosphor material 14 may be present in any form, such as powder, film, phosphor dispersed in organic matrix, glass or composite. The phosphor material may be used as a layer, sheet, strip, dispersed particulates on chip or a combination thereof. In one aspect, the phosphor material is in the form of a sheet or strip mounted or disposed on a surface of the LED light source 12. In one embodiment, the phosphor material 14 may be in glass form. In another embodiment, the phosphor material may be in the form of a phosphor wheel (not shown in figures). A phosphor wheel and related devices are described in PCT Publication No. WO2017/196779. In one aspect, the blue LED is coated or covered with phosphor material. In another aspect, the phosphor material is in powder form and coats or covers the blue LED. In another aspect, a phosphor layer is formed around the blue LED. In another aspect, each phosphor is in a separate layer over the surface of the blue LED. In another aspect, a polymer composite layer comprising the phosphors is formed on the surface of the blue LED.

Examples of LED light sources, which may be used for backlight units are disclosed in U.S. Publication No. 2019/0088827, the entire contents of which are hereby incorporated by reference.

The phosphor material may further include one or more other luminescent materials. In one embodiment, the luminescent materials may be polyfluorenes, such as poly(9,9-dioctyl fluorene) and copolymers thereof, such as poly(9,9′-diocyl-fluorene-co-bis-N,N′-(4-butylphenyl)diphenylamine) (F₈-TFB); poly(vinylcarbazole) and polyphenylenevinylene and their derivatives. Additional luminescent materials, such as blue, yellow, red, orange, or other color phosphors may be used in the phosphor material to customize the white color of the resulting light and produce specific spectral power distributions. Suitable additional phosphors for use in the phosphor material may include, but are not limited to: ((Sr_{1-z}[Ca, Ba, Mg, Zn]z)_{1-(x+w)}[Li, Na, K, Rb]_{w}Ceₓ)₃(Al_{1-y}Si_{y})O_{4+y+3(x-w)}F_{1-y-3(x-w)}, (wherein 0≤x≤1.10, 0≤y≤0.5, 0≤0≤z≤0.5, 0≤w≤x); [Ca,Ce]₃Sc₂S₃O₁₂ (CaSiG); [Sr,Ca,Ba]₃Al₁₋ₓSiₓO₄₊ₓF₁₋ₓ:Ce³⁺ (SASOF)); [Ba,Sr,Ca]₅(PO₄)₃[Cl,F,Br,OH]:Eu²⁺,Mn²⁺; [Ba,Sr,Ca]BPO₅:Eu²⁺,Mn²⁺; [Sr,Ca]₁₀(PO₄)₆*vB₂O₃:Eu²⁺ (wherein 0≤v≤1); Sr₂Si₃O₈*2SrCl₂:Eu²⁺; [Ca,Sr,Ba]₃MgSi₂O₈:Eu²⁺,Mn²⁺; BaAl₈O₁₃:Eu²⁺; 2SrO*0.84P₂O₅*0.16B₂O₃:Eu²⁺; [Ba,Sr,Ca]MgAl₁₀O₁₇:Eu²⁺,Mn²⁺; [Ba,Sr,Ca]Al₂O₄:Eu²⁺; [Y,Gd,Lu,Sc,La]BO₃:Ce³⁺,Tb³⁺; ZnS:Cu⁺,Cl⁻; ZnS:Cu⁺,Al³⁺; ZnS:Ag⁺,Cl⁻; ZnS:Ag⁺,Al³⁺; [Ba,Sr,Ca]₂Si₁₋ₙO₄₋₂ₙ:Eu²⁺ (wherein 0≤n≤0.2); [Ba,Sr,Ca]₂[Mg,Zn]Si₂O₇:Eu²⁺; [Sr,Ca,Ba][Al,Ga,In]₂S₄:Eu²⁺; [Y,Gd,Tb,La,Sm,Pr,Lu]₃ [Al,Ga]₅₋ₐO_{12-3/2a}:Ce³⁺ (wherein (0≤a≤0.5); [Ca,Sr]₈[Mg,Zn](SiO₄)₄Cl₂:Eu²⁺,Mn²⁺; Na₂Gd₂B₂O₇:Ce³⁺,Tb³⁺; [Sr,Ca,Ba,Mg,Zn]₂ P₂O₇:Eu²⁺,Mn²⁺; [Gd,Y,Lu,La]₂O₃:Eu³⁺,Bi³⁺; [Gd,Y,Lu,La]₂O₂S:Eu³⁺,Bi³⁺; [Gd,Y,Lu,La]VO₄:Eu³⁺,Bi³⁺; [Ca,Sr]S:Eu²⁺,Ce³⁺; SrY₂S₄:Eu²⁺; CaLa₂S₄:Ce³⁺; [Ba,Sr,Ca]MgP₂O₇:Eu²⁺,Mn²⁺; [Y,Lu]₂WO6:Eu³⁺,Mo⁶⁺; [Ba,Sr,Ca]_{b}Si_{g}Nₘ:Eu²⁺ (wherein 2b+4g=3m); Ca₃(SiO₄)Cl₂:Eu²⁺; [Lu,Sc,Y,Tb]₂₋ᵤ₋ᵥCeᵥ Ca₁₊ᵤLi_{w}Mg_{2-w}P_{w}(Si,Ge)_{3-w}O_{12-u/2} (where −0.5≤u≤1, 0≤v≤0.1 and 0≤w≤0.2); [Y,Lu,Gd]₂₋ₘ[Y,Lu,Gd]CaₘSi₄N₆₊ₘC₁₋ₘ:Ce³⁺, (wherein 0≤m≤0.5); [Lu,Ca,Li,Mg,Y], alpha-SiAlON doped with Eu²⁺ and/or Ce³⁺; Sr(LiAl₃N₄):Eu²⁺, [Ca,Sr,Ba]SiO₂N₂:Eu²⁺,Ce³⁺; beta-SiAlON:Eu²⁺, 3.5MgO*0.5MgF₂*GeO₂:Mn⁴⁺; Ca_{1-c-f}Ce_{c}Eu_{f}Al_{1+c}Si_{1-c}N₃, (where 0≤c≤0.2, 0≤f≤0.2); Ca₁₋ₕ₋ᵣCeₕEuᵣAl₁₋ₕ[Mg,Zn]ₕSiN₃, (where 0≤h≤0.2, 0≤r≤0.2); Ca_{1≤2s-t}Ceₛ[Li,Na]ₛEuₜAlSiN₃, (where 0≤s≤0.2, 0≤t≤0.2, s+t>0); [Sr,Ca]AlSiN₃:Eu²⁺, Ce³⁺, and Li₂CaSiO₄:Eu²⁺. In addition, the light emitting layer may include a blue, yellow, orange, green or red phosphorescent dye or metal complex, a quantum dot material, or a combination thereof. Materials suitable for use as the phosphorescent dye include, but are not limited to, tris(1-phenylisoquinoline) iridium (III) (red dye), tris(2-phenylpyridine) iridium (green dye) and Iridium (III) bis(2-(4,6-difluorephenyOpyridinato-N,C2) (blue dye). Commercially available fluorescent and phosphorescent metal complexes from ADS (American Dyes Source, Inc.) may also be used. ADS green dyes include ADS060GE, ADS061GE, ADS063GE, and ADS066GE, ADS078GE, and ADSO90GE. ADS blue dyes include ADS064BE, ADS065BE, and ADS070BE. ADS red dyes include ADS067RE, ADS068RE, ADS069RE, ADS075RE, ADS076RE, ADS067RE, and ADS077RE.

The ratio of each of the individual phosphors in the phosphor material may vary depending on the characteristics of the desired light output. The relative proportions of the individual phosphors in the various phosphor materials may be adjusted such that when their emissions are blended and employed in a device, for example a lighting apparatus, there is produced visible light of predetermined x and y values on the CIE chromaticity diagram.

Other additional luminescent materials suitable for use in the phosphor material may include a quantum dot material. In one embodiment, the display may include a quantum dot enhanced film. Exemplary quantum dot materials may be a group II-VI compound, a group III-V compound, a group IV-IV compound, a group IV compound, a group I-III-VI2 compound or a combination thereof. Examples of group II-VI compounds include but are not limited to CdSe, CdTe, CdS, ZnSe, ZnTe, ZnS, HgTe, HgS, HgSe, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe, or combinations thereof. Examples of group III-V compounds include, but are not limited to GaN, GaP, GaAs, AlN, AlP, AlAs, InN, InP, InAs, GaNP, GaNAs, GaPAs, AlNP, AlNAs, AlPAs, InNP, InNAs, InPAs, GaAlNP, GaAlNAs, GaAlPAs, GalnNP, GalnNAs, GalnPAs, InAlNP, InAlNAs, InAlPAs, and combinations thereof. Examples of group IV compounds include, but are not limited to Si, Ge, SiC, and SiGe. Examples of group I-III-VI2 chalcopyrite-type compounds include, but are not limited to CuInS2, CuInSe2, CuGaS2, CuGaSe2, AgInS2, AgInSe2, AgGaS2, AgGaSe2 and combinations thereof.

The QD materials may be a core/shell QD, including a core, at least one shell coated on the core, and an outer coating including one or more ligands, preferably organic polymeric ligands. Exemplary materials for preparing core-shell QDs include, but are not limited to, Si, Ge, Sn, Se, Te, B, C (including diamond), P, Co, Au, BN, BP, BAs, AlN, AlP, AlAs, AlSb, GaN, GaP, GaAs, GaSb, InN, InP, InAs, InSb, AlN, AlP, AlAs, AlSb, GaN, GaP, GaAs, GaSb, ZnO, ZnS, ZnSe, ZnTe, CdS, CdSe, CdSeZn, CdTe, HgS, HgSe, HgTe, BeS, BeSe, BeTe, MgS, MgSe, MnS, MnSe, GeS, GeSe, GeTe, SnS, SnSe, SnTe, PbO, PbS, PbSe, PbTe, CuF, CuCl, CuBr, CuI, Si₃N₄, Ge₃N₄, Al₂O₃, (Al, Ga, In)₂(S, Se, Te)₃, Al₂CO, and appropriate combinations of two or more such materials. Exemplary core-shell luminescent nanocrystals include, but are not limited to, CdSe/ZnS, CdSe/CdS, CdSe/CdS/ZnS, CdSeZn/CdS/ZnS, CdSeZn/ZnS, InP/ZnS, PbSe/PbS, PbSe/PbS, CdTe/CdS and CdTe/ZnS. Other examples of the quantum dot materials include perovskite quantum dots such as CsPbX3, where X is Cl, Br, I or a combination thereof. In one aspect, the red phosphor may be a quantum dot material.

FIG. 3 illustrates a lighting apparatus or lamp 20, in accordance with some embodiments. The lighting apparatus 20 includes an LED chip 22, and leads 24 electrically attached to the LED chip 22. The leads 24 may comprise thin wires supported by a thicker lead frame(s) 26 or the leads 24 may comprise self supported electrodes and the lead frame may be omitted. The leads 24 provide current to LED chip 22 and thus cause it to emit radiation.

The LED chip 22 may be encapsulated within an envelope 28. The envelope 28 may be formed of, for example glass or plastic. The LED chip 22 may be enclosed by an encapsulant material 32. The encapsulant material 32 may be a low temperature glass, or a polymer or resin known in the art, for example, an epoxy, silicone, epoxy-silicone, acrylate or a combination thereof. In an alternative embodiment, the lighting apparatus 20 may only include the encapsulant material 32 without the envelope 28. Both the envelope 28 and the encapsulant material 32 should be transparent to allow light to be transmitted through those elements.

With continued reference to FIG. 3, a layer 34 of the phosphor material as described herein is disposed on a surface 21 of the LED chip 22. The layer 34 may be disposed by any appropriate method, for example using a slurry prepared by mixing silicone and the phosphor material. In one such method, a silicone slurry in which the particles of the phosphor material are randomly suspended, is placed around the LED chip 22. This method is merely exemplary of possible positions of the layer 34 and LED chip 22. As illustrated, the layer 34 may be disposed for example, coated over or directly on the surface 21 of the LED chip 22 by coating and drying the slurry over the LED chip 22. The surface 21 is a light emitting surface of the LED chip 22. The light emitted by the LED chip 22 mixes with the light emitted by the phosphor material of the layer 34 to produce desired emission.

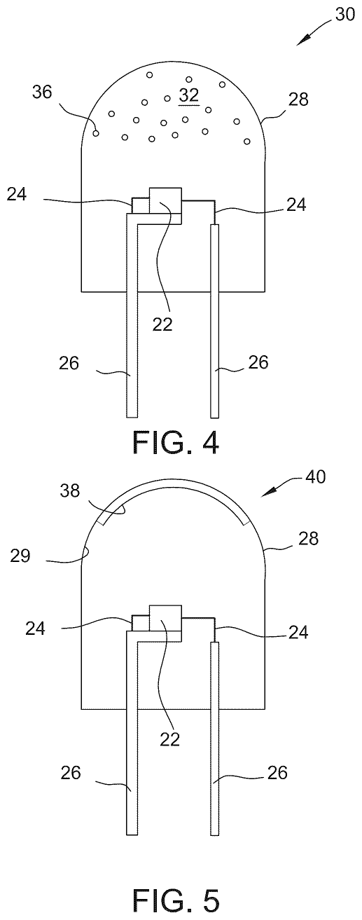

In some other embodiments, the phosphor material as described herein is interspersed within the encapsulant material 32, instead of being disposed directly on the LED chip 22 as shown in FIG. 3. FIG. 4 illustrates a lighting apparatus 30 that includes particulates 36 of the phosphor material interspersed within a portion of the encapsulant material 32. The particulates of the phosphor material may be interspersed throughout the entire volume of the encapsulant material 32. Blue light emitted by the LED chip 22 mixes with the light emitted by the particulates 36 of the phosphor material, and the mixed light transmits out from the lighting apparatus 30.

In some other embodiments, a layer 38 of the phosphor material as herein descried, is coated onto a surface of the envelope 28 as illustrated in FIG. 5 showing an exemplary embodiment of a lighting apparatus 40, instead of being formed over the LED chip 22 (FIG. 3). As shown, the layer 38 is coated on an inside surface 29 of the envelope 28, although the layer 38 may be coated on an outside surface of the envelope 28, if desired. The layer 38 may be coated on the entire surface of the envelope 28 or only a top portion of the inside surface 29 of the envelope 28. The UV/blue light emitted by the LED chip 22 mixes with the light emitted by the layer 38, and the mixed light transmits out. Of course, the phosphor material may be located in any two or all three locations (as shown in FIGS. 3-5) or in any other suitable location, such as separately from the envelope 28 or integrated into the LED chip 22.

In any or all the above configurations, the lighting apparatus 20, 30 or 40 shown respectively in FIG. 3, FIG. 4 or FIG. 5 include the backlight unit 10. The lighting apparatus 20, 30, 40 may also include a plurality of scattering particles (not shown), which are embedded in the encapsulant material 32. The scattering particles may comprise, for example, alumina, silica, zirconia, or titania. The scattering particles effectively scatter the directional light emitted from the LED chip 22, preferably with a negligible amount of absorption.

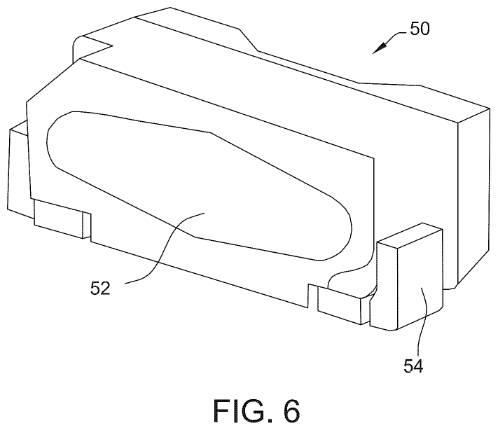

Some embodiments are directed to a backlight apparatus 50 as illustrated in FIG. 6. The backlight apparatus 50 includes a surface mounted device (SMD) type light emitting diode for backlight or display applications. This SMD is a “side-emitting type” and has a light-emitting window 52 on a protruding portion of a light guiding member 54. An SMD package may comprise an LED chip as defined above, and a phosphor material as described herein. In some embodiments, the SMD package may comprise an LED chip as defined above, and a phosphor material as described herein.

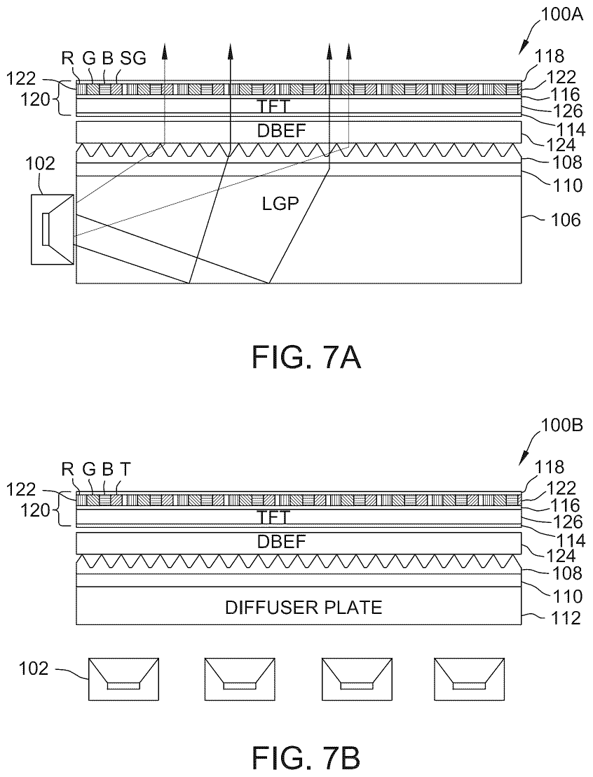

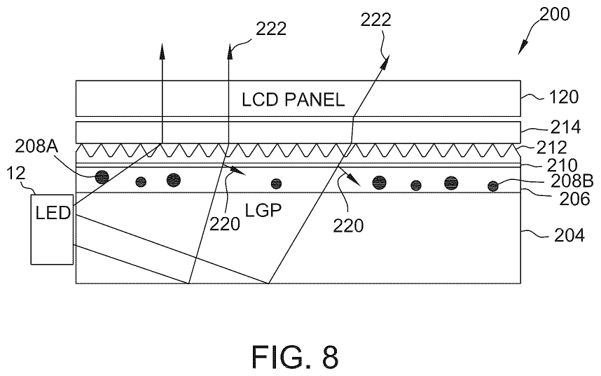

The LED backlight unit generates a white light, which passes through the LCD panel. The LCD panel is configured to receive the white backlight from the LED backlighting and display color images. In one aspect, a waveguide or light guide plate may be used to guide light emitted from the LED backlighting to the LCD panel. FIG. 7A shows an exemplary embodiment of a liquid crystal display (LCD) with an edge lit backlight configuration. LCD 100A includes an array of LED backlighting 102 along one or more edges of the LCD 100A, light guide panel 106 and an LCD panel 120. The LCD 100A uses the LCD panel 120 with control electronics and the LED backlighting 102 to produce color images. The LED backlighting 102 includes the backlight unit 10, as previously described in FIG. 2 and includes a blue LED light source 12 and phosphor material 14. The backlighting 102 may be a lighting apparatus 20, 30, 40 as shown in FIG. 3, 4 or 5. The phosphor material 14 may be located remotely at a distance from the LED light source 12 as shown in FIG. 8.

The liquid crystal display panel 120 includes a four color filter 122 arranged in subpixels. The color filters 122 transmit a light having a specific wavelength of white light incident from the LED backlight unit 10. The color filters 122 transmit wavelengths of light corresponding to the color of each filter, and absorb other wavelengths.

The LCD panel 120 includes a front polarizer 118, a rear polarizer 114, a color filter 122, a thin film transistor 126 (TFT) and liquid crystal 116, as well as electrodes (not shown). Normally, the LCD panel 120 is opaque. The color filters 122 are positioned between the liquid crystal 116 and the front polarizer 118. The thin film transistor 126 is positioned between the liquid crystal 116 and the rear polarizer 114. Each pixel has a corresponding transistor or switch for controlling voltage applied to the liquid crystal 116. The front and rear polarizers 118 and 114 may be set at right angles. The front polarizer 118 filters light radiated from the LED backlighting 102 and transmits only light of a first polarized direction of the light. The front polarizer 118 may be configured as a horizontal polarized light filter or as a vertical polarized filter. The rear polarizer 114 is a polarized light filter, which may be inclined by 90 degrees to the front polarizer 118. In one aspect, the polarizers may be polarizing films on glass filters or substrates. After passing through the front polarizer 118, the polarized light is transmitted through the liquid crystal 116 and the thin film transistor 126. The liquid crystal 116 includes a plurality of liquid crystal cells with liquid crystal molecules of rod-shaped polymers. Each cell includes a common electrode and a sub pixel electrode. Liquid crystal molecules are twisted when there is no electricity, but when a voltage is applied across the liquid crystal 116, the rod-shaped polymers align with the electric field and untwist such that the voltage controls the light output from the front polarizer 118. For example, when a voltage is applied to the liquid crystal 116, the liquid crystal 116 rotates so that there is a light output from the front polarizer 118. The thin film transistor 126 includes a plurality of transistors for turning on or off each liquid crystal cell within the liquid crystal 116. Each film transistor is electrically connected to the subpixel electrode in each liquid crystal cell in the liquid crystal 116. The liquid crystal 116 actively transmits or blocks light and is configured to display images. A four color filter 122 applies color to the white light passing through the LCD panel 120.

The white light from the LED backlighting 102 travels toward the light guide panel 106, through diffuser film 110 and prism 108, as well as double brightness enhanced film 124, which provides a uniform light backlight for the liquid crystal display panel 120.

The LED backlighting 102 and LCD 100A may include additional components typical in an optical stack. In one aspect, diffusers, reflectors or glass filters may be provided. In another aspect, a cover glass may cover the optical stack.

FIG. 7B illustrates an exemplary embodiment of a direct lit backlight configuration for a liquid crystal display (LCD) 100B. As shown, the main differences from the edge lit configuration 100A include different arrangement of a number of LED backlighting 102 and the absence of light guide panel 106. The LED backlighting 102 are arranged to directly provide light to a diffuser film 110, which is supported by a diffuser plate 112.

The four color filter 122 mixes and filters the white light generated by the LED backlighting 102 as it passes through the LCD panel 120 to achieve a color image or display. In one aspect, the four color filter 122 has a red filter, a green filter, a blue filter and a saturated green (SG) filter (“RGGB”) and is shown in FIG. 7A. The RGGB color filter produces a pixel with a red subpixel, a green subpixel, a blue subpixel and a saturated green subpixel. In another aspect, the four color filter has a red filter, a green filter, a blue filter and a teal or cyan filter (“RGBT”) and is shown in FIG. 7B. The RGBT color filter produces a pixel with a red subpixel, a green subpixel, a blue subpixel and a teal subpixel. The RGGB and RGBT filters can be used in any liquid crystal display and a liquid crystal display may include RGGB filters, RGBT filters or both.

FIG. 8 illustrates an exemplary embodiment of a backlight unit or module 200 that includes LED light source 12 as previously described in FIG. 2, light guide panel 204, remote phosphor package 206, dichroic filter 210 and LCD panel 120 as previously described in FIG. 7A. Backlight unit 200 may also optionally include a prism 212 and a double brightness enhanced film 214. The LED light source 12 is a blue emitting LED. To produce even lighting, blue light from the LED light source 12 first passes through light guide panel 204, which diffuses the blue light. Generally, there is an air space between the LCD panel 120 and the double brightness enhanced film (DBEF) 214. The double brightness enhanced film is a reflective polarizer film which increases efficiency by repeatedly reflecting any unpolarized light back, which would otherwise be absorbed by the LCD's rear polarizer 118. The double brightness enhanced film 214 is placed behind the LCD panel 120 without any other film in-between. The double brightness enhanced film 214 may be mounted with its transmission axis substantially parallel to the transmission axis of the rear polarizer 118. The double brightness enhanced film 214 helps recycle the white light 220 that would normally be absorbed by the rear polarizer 118 of the LCD panel 120, and thus, increases the brightness of the LCD panel 120 and light 222 emitting from the LCD panel 120. In another embodiment, the prism 212 may be removed or substituted by other brightness enhancement components. In another aspect, the double brightness enhanced film may be removed.

The backlight unit or module 200 includes a remote phosphor package 206 located remotely at a distance from the LED light source 12. The remote phosphor package 206 includes the phosphor material including particles of the green-emitting U⁶⁺-containing phosphor 208A and the red phosphor 208B. The remote phosphor package 206 is remote in the sense that the primary light source and the phosphor material are separate elements, and the phosphor material is not integrated with the primary light source as a single element. Primary light is emitted from the primary light source and travels through one or more external media to radiationally couple the LED light source 12 to the phosphor material in the remote phosphor package 206. The remote phosphor package 206 additionally includes a matrix material in which the phosphor material is embedded or otherwise disposed. Suitable matrix materials are transparent, non-yellowing and chemically and optically compatible with the backlight unit or module components. In one aspect, the matrix materials have low oxygen and moisture permeability, exhibit high photo- and chemical-stability, exhibit favorable refractive indices, and adherent properties to provide an air-tight seal to protect the phosphor material within the remote phosphor package 206.

Examples of matrix materials include but are not limited to epoxies, acrylates, norborene, polyethylene, poly(vinyl butyral):poly(vinyl acetate), polyurea, polyurethanes; silicones and silicone derivatives including, but not limited to, amino silicone (AMS), polyphenylmethylsiloxane, polyphenylalkylsiloxane, polydiphenylsiloxane, polydialkylsiloxane, silsesquioxanes, fluorinated silicones, and vinyl and hydride substituted silicones; acrylic polymers and copolymers formed from monomers including, but not limited to, methylmethacrylate, butylmethacrylate, and laurylmethacrylate; styrene-based polymers such as polystyrene, amino polystyrene (APS), and poly(acrylonitrile ethylene styrene) (AES); polymers that are crosslinked with difunctional monomers, such as divinylbenzene; cross-linkers suitable for cross-linking ligand materials, epoxides which combine with ligand amines (e.g., APS or PEI ligand amines) to form epoxy polymers.

It will be appreciated by those skilled in the art that a backlight unit or module according to an aspect of the disclosure may vary in configuration. For example, a direct lit configuration may be used, similar to the direct light configuration shown in FIG. 7B.

In one aspect, the display described herein takes advantage of the unique spectral properties of U⁶⁺ emission. As explained previously, the U⁶⁺ ion can emit in wavelengths covering the whole visible spectrum. The emission wavelength of U⁶⁺ depends on the coordination of the U⁶⁺ and the host lattice. When the U⁶⁺ peak emission is in the green range (490 nm to 560 nm), it can emit as a broad band in the green range with an FWHM of 40-65 nm or as a line emission composed of five peaks in the green range (490 nm to 560 nm) with each peak having a FWHM of 2-15 nm. In one aspect, one of the spectral peaks may be isolated to create a fourth subpixel. In one embodiment, the fourth subpixel is a teal subpixel, which creates a safe eye display having reduced blue emission. In another embodiment, the fourth subpixel is a saturated green subpixel, which creates an ultra-high gamut display.

In one embodiment, the four color RGBT or RGGB filters in with the LED backlight unit expand the color gamuts of the displays. In one aspect, the first emission peak of the U⁶⁺ line emission is isolated. A four color RGBT filter is applied to the white light generated by the LED backlight unit and exiting the LCD panel and produces a color display with an expanded color gamut. In one aspect, the LED backlight unit comprises a blue LED, a red phosphor and a U⁶⁺-containing phosphor. The U⁶⁺-containing phosphor in the LED backlight unit has a line emission in the wavelength of about 470 nm to about 505 nm. In another embodiment, a line emission may be in a range from about 485 nm to about 505 nm. In another embodiment, the line emission is in a range from about 480 nm to about 500 nm. In another embodiment, a line emission may be in a range from about 490 nm to about 500 nm. In another embodiment, a line emission may be in a range from about 495 nm to about 500 nm. In another aspect, the U⁶⁺-containing phosphor emits as a distinct line with full width at half maximum (FWHM) of 5 nm or less. In another aspect, the U⁶⁺-containing phosphor emits as a distinct line with FWHM from about 2 nm to about 5 nm. In another aspect, the U⁶⁺-containing phosphor emits as a distinct line with FWHM at about 2 nm. The RGBT filter splits the light into components of red, blue, green and teal, each with its own color point. The four color points can be graphed in either (ccx, ccy) or (u′,v′) color space. Each of the color points are connected and a four-sided figure is formed, which defines the color gamut or color space of the display.

The narrow peak emission or line emission of the U⁶⁺-containing phosphor within the transmittance range of the teal color filter results in a well-defined four-sided figure with an expanded color gamut. Overlap of the display gamut with a defined color space, such as the color gamut for REC2020, represents the % coverage of that particular space.

In one aspect, the second emission peak of the U⁶⁺ line emission is isolated. A four color RGGB filter is applied to the white light generated by the LED backlight unit and exiting the LCD panel and produces a color display with an expanded color gamut. In one aspect, the LED backlight unit comprises a blue LED, a red phosphor and a U⁶⁺-containing phosphor. The U⁶⁺-containing phosphor in the LED backlight unit has a line emission in the wavelength range from about 505 nm to about 530 nm. In another embodiment, the U⁶⁺-containing phosphor has a line emission in a wavelength range from about 510 nm to about 530 nm. In another embodiment, the line emission may be in a range from about 515 nm to about 525 nm, In another embodiment, the line emission may be in a range from about 518 nm to about 525 nm. In another embodiment, the line emission may be in a range from about 520 nm to about 525 nm. In another aspect, the U⁶⁺-containing phosphor emits as a distinct line with full width at half maximum (FWHM) of 5 nm or less. In another aspect, the U⁶⁺-containing phosphor emits as a distinct line with FWHM from about 2 nm to about 5 nm. In another aspect, the U⁶⁺-containing phosphor emits as a distinct line with FWHM at about 2 nm. The RGGB filter splits the light into components of red, blue, green and saturated green with its own color point. The four color points can be graphed in either (ccx, ccy) or (u′,v′) color space. A triangle figure is formed by connecting the color points, which defines the color gamut or color space of the display.

The narrow peak emission or line emission of the U⁶⁺-containing phosphor within the transmittance range of the saturated green color filter results in a highly saturated green color point, which creates a display with an expanded ultra-high color gamut. Overlap of the display gamut with a defined color space, such as the color gamut for REC2020, represents the % coverage of that particular space. When pushing displays toward higher gamut the overall intensity of the display is reduced because the green point is becoming farther from the eye sensitivity curve, by having two green subpixels the display can easily be switched from one color space to another.

In one aspect, the first emission peak of the U⁶⁺ line emission is isolated. A four color RGBT filter is applied to the white light generated by the LED backlight unit and exiting the LCD panel and produces a color display with reduced blue light. In one aspect, the LED backlight unit comprises a blue LED, a red phosphor and a U⁶⁺-containing phosphor. The U⁶⁺-containing phosphor in the LED backlight unit has a line emission in the wavelength of about 470 nm to about 505 nm. In another embodiment, a line emission may be in a range from about 485 nm to about 505 nm. In another embodiment, the line emission is in a range from about 480 to about 500 nm. In another embodiment, a line emission may be in a range from about 490 nm to about 500 nm. In another embodiment, a line emission may be in a range from about 495 nm to about 500 nm. In another aspect, the U⁶⁺-containing phosphor emits as a distinct line with full width at half maximum (FWHM) of 5 nm or less. In another aspect, the U⁶⁺-containing phosphor emits as a distinct line with FWHM from about 2 nm to about 5 nm. In another aspect, the U⁶⁺-containing phosphor emits as a distinct line with FWHM at about 2 nm. The RGBT filter splits the light into components of red, blue, green and teal, each with its own color point. The four color points can be graphed in either (ccx, ccy) or (u′,v′) color space. Each of the color points are connected and a four-sided figure is formed, which defines the color gamut or color space of the display, Within each color space, there is a D65 white color point, which is a true white point for the color space.

The narrow peak emission or line emission of the U⁶⁺-containing phosphor within the transmittance range of the teal color filter results in a well-defined four-sided figure with an expanded color gamut. A tie line can be drawn between the teal color point and the red color point of the color gamut. In one aspect, the tie line is below the D65 white point. This allows for the display to the gamut area created by the teal-red-green color triangle. The amount of blue light emitted through the display is reduced, as the blue subpixel is only used to display colors connected by the blue-teal-red color triangle. Where a tie line between the teal color point and the red color point is below the D65 white point, most of the colors in the color space can be generated with the red subpixel, green subpixel and teal subpixel without the use of the blue subpixel. As the teal color filter transmits light at wavelengths within the range of about 460 nm to about 550 nm, the teal subpixel does not include blue wavelengths in the range of 415 nm to 455 nm, which are considered to be unsafe for human eyes. Activating the teal subpixel instead of the blue subpixel to produce the color display reduces hazardous blue light emissions from the display.

In other aspects, the display can be tuned for optimized performance, the spectral properties of the U⁶⁺ phosphor can be tuned, the ratio of the color pigment blend can be adjusted and the optical density of the color filter can be changed to optimize the desired display.

### EXAMPLES

### Example 1

White light is produced by an LED backlight unit including a blue LED, PFS red phosphor (K₂SiF₆:Mn⁴⁺) and U⁶⁺-containing phosphor, (BaZn₂(PO₄)₂):U⁶⁺. In Sample U0407 B HG, a four color filter RGGB is applied to the white light from the LED backlight unit that passes through an LCD panel. In comparative sample U0407 B, a three color filter RGB is applied to the white light from the LED backlight unit that passes through an LCD panel. The RGGB filter splits the light into components of red, blue, green and saturated green, each having its own color point. The four color points can be graphed in either (ccx, ccy) or (u′,v′) color space. A triangle figure is formed by connecting the color points, which defines the color gamut or color space of the display. The RGB filter splits the light into components of red, blue and green each having its own color point. The three color points can be graphed in either (ccx, ccy) or (u′,v′) color space. A triangle figure is formed by connecting the color points, which defines the color gamut or color space of the display.

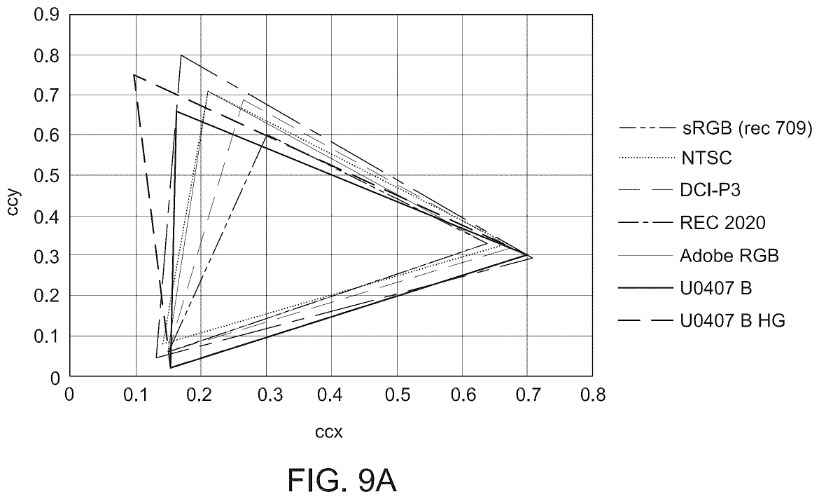

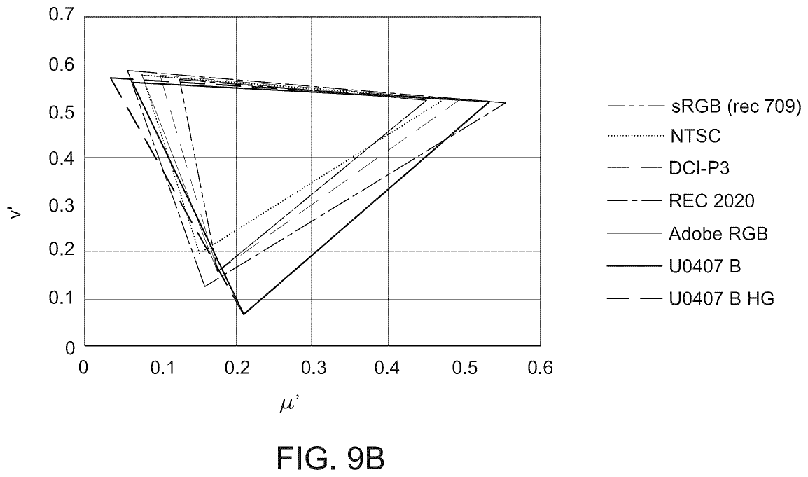

FIGS. 9A and 9B provide color spaces in (ccx, ccy), FIG. 9A and (u′,v′), FIG. 9B and compares the color gamut obtained for Sample U0407 B HG with a color gamut obtained for comparative Sample U0407 B. The color gamut for U0407 B HG using the four color filter has an expanded gamut coverage compared with the color gamut obtained by the RGB three color filter (U0407 B). FIGS. 9A and 9B also compares the color gamuts for the three color RGB filter and the four color RGGB filter with color standards, such as sRGB, NTSC (National Television System Committee), DCI-P3, REC2020 and Adobe RGB. The color gamut obtained with the four color RGGB filter demonstrates improved coverage in relation to the various color standards.

A white light is produced by an LED backlight unit including a blue LED, PFS red phosphor (K₂SiF₆:Mn⁴⁺) and U⁶⁺-containing phosphor, (BaZn₂(PO₄)₂):U⁶⁺. In sample U0407, a four color filter RGBT is applied to the white light from the LED backlight unit that passes through an LCD panel. In comparative sample U0407 (3), a three color filter RGB is applied to the white light from the LED backlight unit that passes through an LCD panel. The RGBT filter splits the light into components of red, blue, green and teal, each having its own color point. The four color points can be graphed in either (ccx, ccy) or (u′,v′) color space. A four-sided figure is formed by connecting the color points, which defines the color gamut or color space of the display. The RGB filter splits the light into components of red, blue and green each having its own color point. The three color points are graphed in (ccx, ccy) and (u′,v′) color space. A triangle figure is formed by connecting the color points, which defines the color gamut or color space of the display.

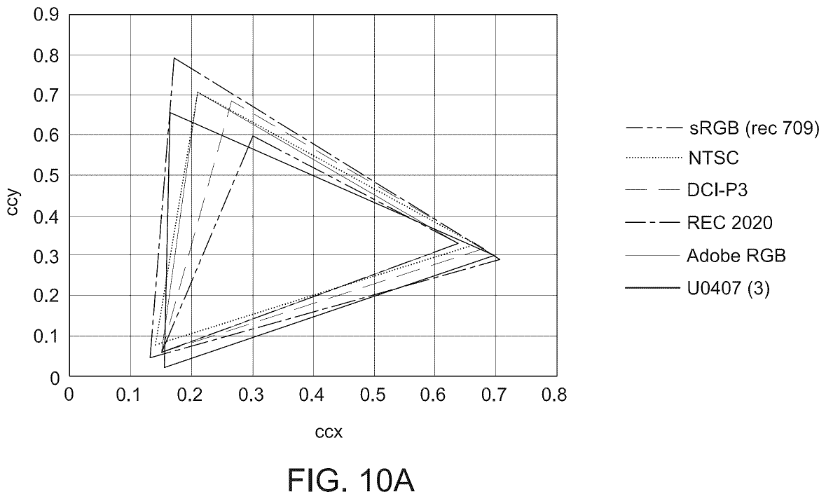

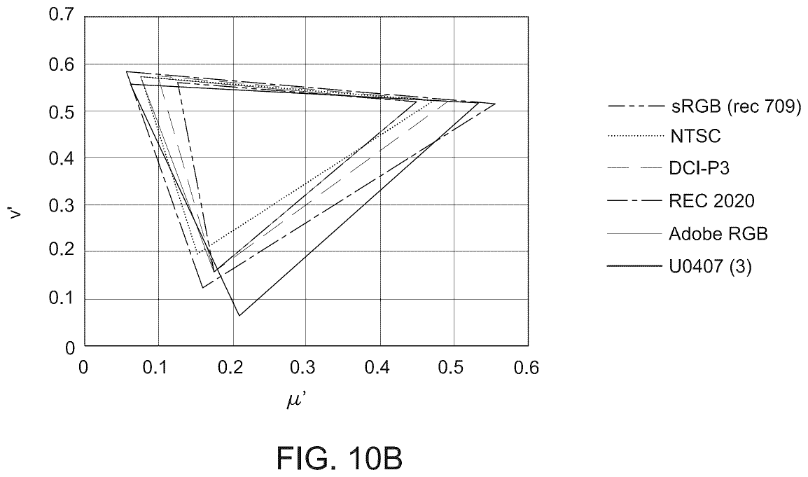

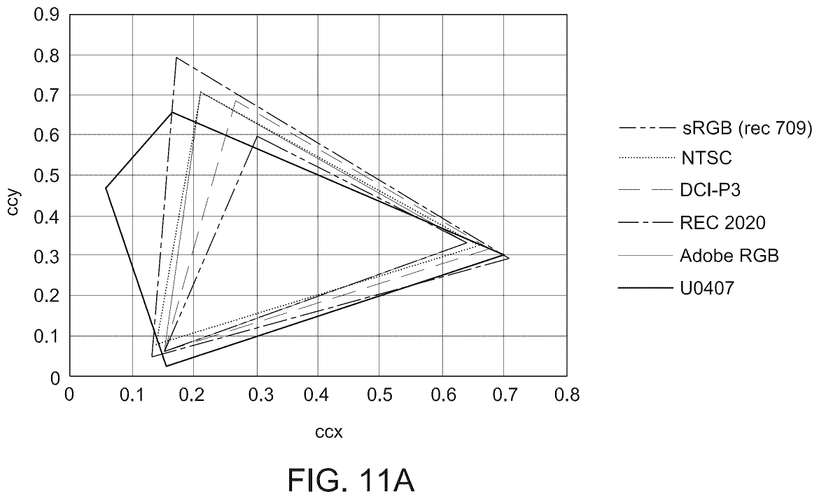

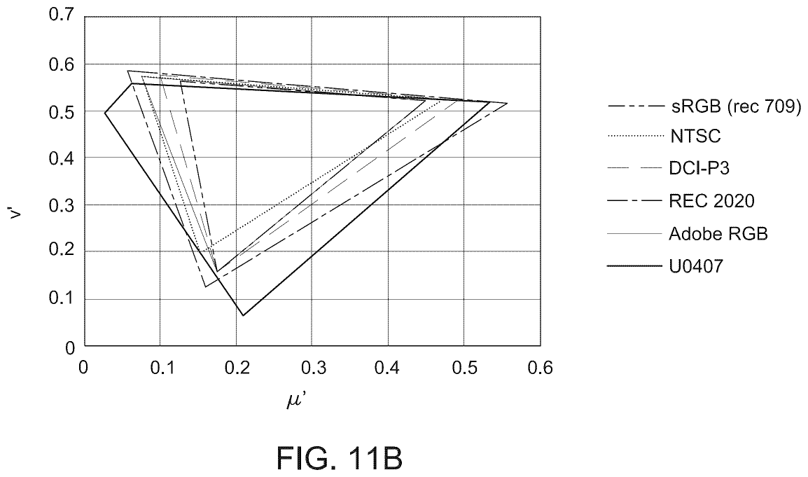

FIGS. 10A and 10B provide color spaces in (ccx,ccy), FIG. 10A, and (u′,v′), FIG. 10B, shows the color gamut for comparative sample U0407 (3) and color standards, such as such as sRGB, NTSC (National Television System Committee), DCI-P3, REC2020 and Adobe RGB. FIGS. 11A and 11B provide color spaces in (ccx, ccy), FIG. 11A, and (u′,v′), FIG. 11B, shows the color gamut obtained by using the RGBT four color filter and color standards, such as sRGB, NTSC (National Television System Committee), DCI-P3, REC2020 and Adobe RGB. The color gamut obtained with the four color RGBT filter has an expanded gamut coverage when compared with the color gamut for comparative sample U0407 (3) and improved coverage in relation to the various color standards.

Preparation of BaZn₂(PO₄)₂. BaCO₃, ZnO, (NH₄)₂HPO₄ (DAP) and UO₂ were weighed out in a ratio of 0.99:2:2.05:0.01 in a Nalgene bottle and ball milled for two hours. After the mixture was thoroughly blended the powder was transferred into an alumina crucible and fired at 500° C./5 hrs/air to decompose the DAP. After firing the powder was placed back into the Nalgene bottle and ball milled for another two hours. Then the powder mixture was placed back into an alumina crucible and re-fired at 1000° C./5 hrs/air.

### Example 2

White light is produced by an LED backlight unit including a blue LED, PFS red phosphor (K₂SiF₆:Mn⁴⁺), U⁶⁺-containing phosphor, (K₃UO₂F₅) and Beta-SiAlON. In Sample U0607 C+B HG, a four color filter RGGB is applied to the white light from the LED backlight unit that passes through an LCD panel. In comparative sample U0607 C+B, a three color filter RGB is applied to the white light from the LED backlight unit that passes through an LCD panel. The RGGB filter splits the light into components of red, blue, green and saturated green, each having its own color point. The four color points can be graphed in either (ccx, ccy) or (u′,v′) color space. A triangle figure is formed by connecting the color points, which defines the color gamut or color space of the display. The RGB filter splits the light into components of red, blue and green each having its own color point. The three color points can be graphed in either (ccx, ccy) or (u′,v′) color space. A triangle figure is formed by connecting the color points, which defines the color gamut or color space of the display.

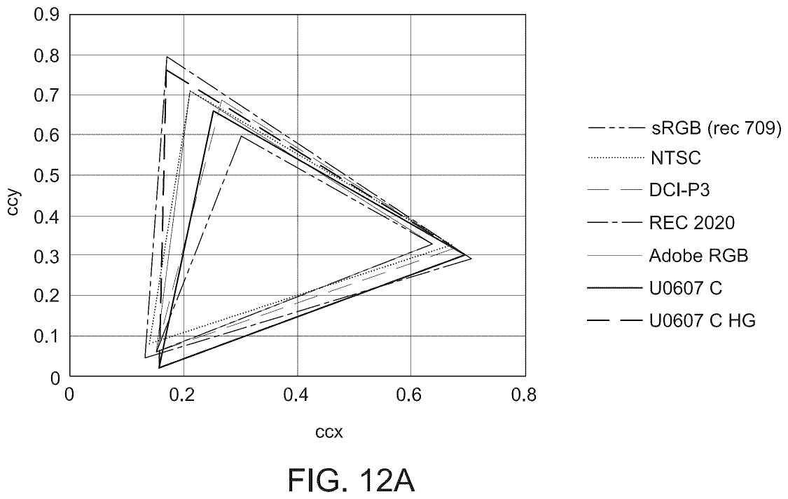

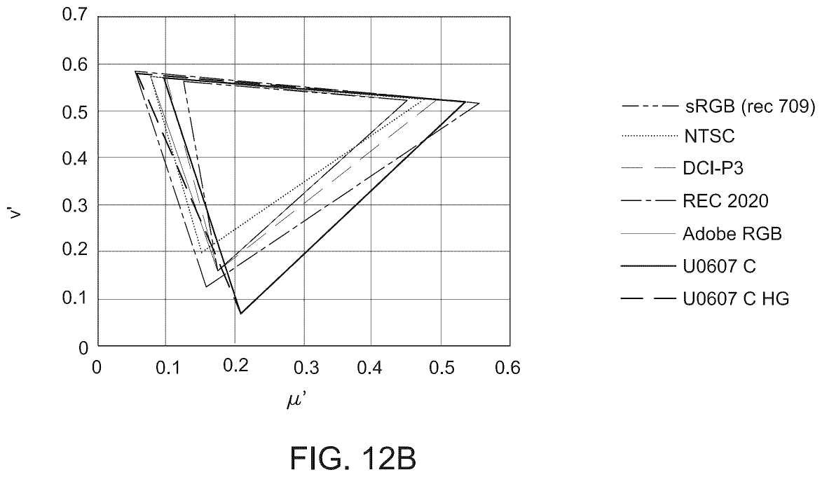

FIGS. 12A and 12B provide color spaces in (ccx, ccy), FIG. 12A, and (u′,v′), FIG. 12B, and compares the color gamut obtained for Sample U0607 C+B HG with a color gamut obtained for comparative Sample U0607 C+B). The color gamut for the four color filter is shown with an expanded gamut coverage compared with the color gamut obtained by the RGB three color filter. FIGS. 12A and 12B also compare the color gamuts for the three color RGB filter and the four color RGGB filter with color standards, such as sRGB, NTSC (National Television System Committee), DCI-P3, REC2020 and Adobe RGB. The color gamut obtained with the use of an additional green phosphor and a four color RGGB filter demonstrates improved coverage in relation to the various color standards.

Preparation of K₃UO₂F₅—In beaker 1, 1 g of UO₂(NO₃)₂-6H₂O was dissolved in 1 ml of water. In beaker 2, 12 g of KF was dissolved in 12 ml water. Beaker 1 was added to beaker 2 and a precipitate of K₃UO₂F₅ was formed. The product was filtered, washed and then dried at 110° C. in a drying oven.

### Example 3

In Sample U0607 A, a white light is produced by an LED backlight unit. The LED backlight unit including a blue LED, PFS red phosphor (K₂SiF₆:Mn⁴⁺) and U⁶⁺-containing phosphor, (K₃UO₂F₅). A four color filter RGBT is applied to the white light from the LED backlight unit that passes through an LCD panel. The RGBT filter splits the light into components of red, blue, green and teal, each having its own color point. The four color points can be graphed in either (ccx, ccy) or (u′,v′) color space. Each of the color points are connected and a four-sided figure is formed, which defines the color gamut or color space of the display, Within each color space, there is a D65 white color point, which is a true white point for the color space.

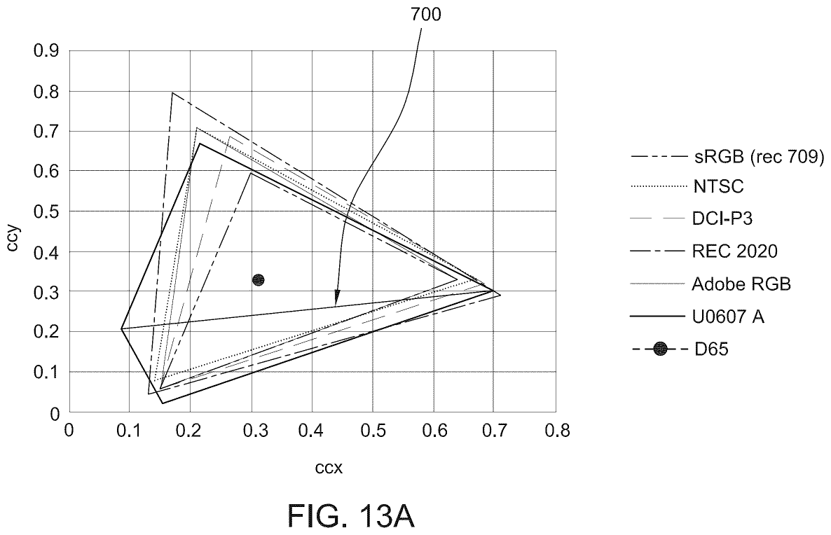

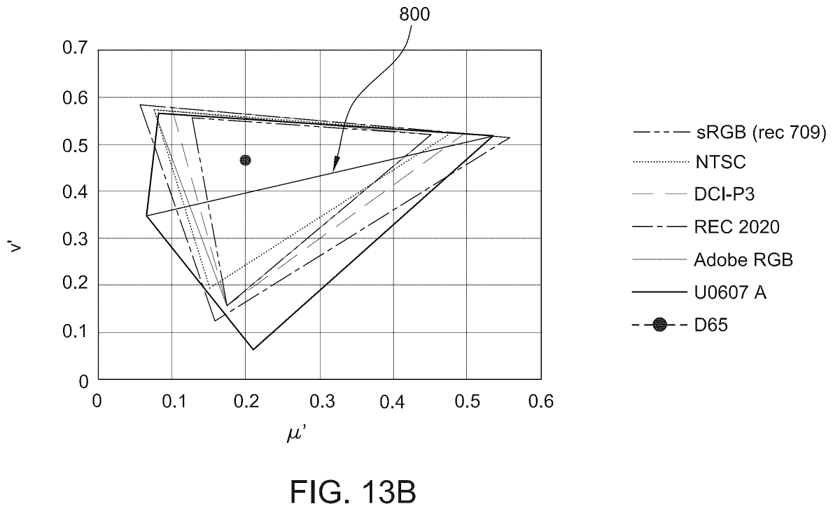

FIGS. 13A and 13B provide color spaces in (ccx,ccy), FIG. 13A, and (u′,v′), FIG. 13B, and demonstrates how the addition of the teal pixel color point defines a color gamut with a four-sided figure. A tie line 700, 800 can be drawn between the teal color point and the red color point of the color gamut. In one aspect, the tie line 700, 800 is below the D65 white point. Where a tie line 700, 800 between the teal color point and the red color point falls below the D65 point, then most of the colors in the color space can be generated with the red subpixel, green subpixel and teal subpixel without the use of the blue subpixel. As the teal color filter transmits light at wavelengths within the range of about 460 nm to about 550 nm, the teal subpixel does not include blue wavelengths within the range of about 460 nm to about 550 nm, the teal subpixel does not include blue wavelengths in the range of 415 nm to 455 nm, which are considered to be unsafe for human eyes. Activating the teal subpixel instead of the blue subpixel to produce the color display reduces hazardous blue light emissions from the display.

FIGS. 13A and 13B compares the color gamut obtained by using the RGBT four color filter to color standards, such as sRGB, NTSC (National Television System Committee), DCI-P3, REC2020 and Adobe RGB. The color gamut obtained with the four color RGBT filter has an expanded gamut coverage and improved coverage in relation to the various color standards.

### Example 4

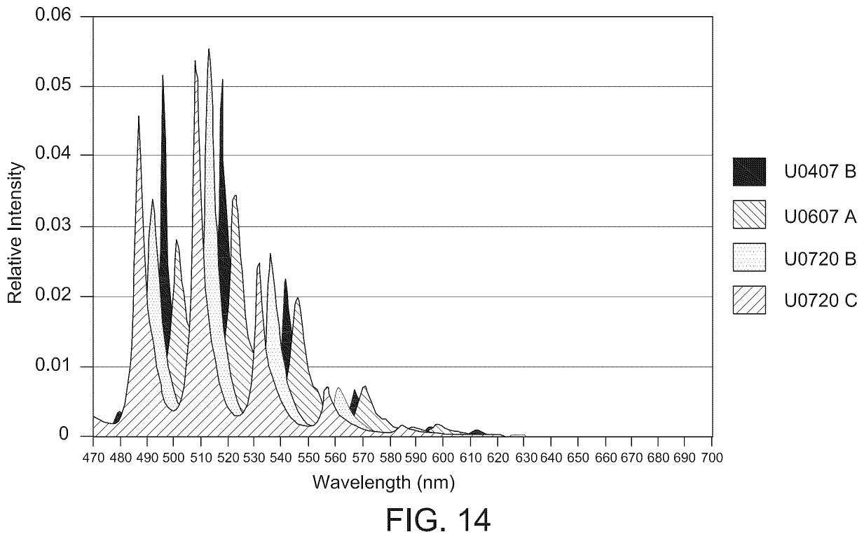

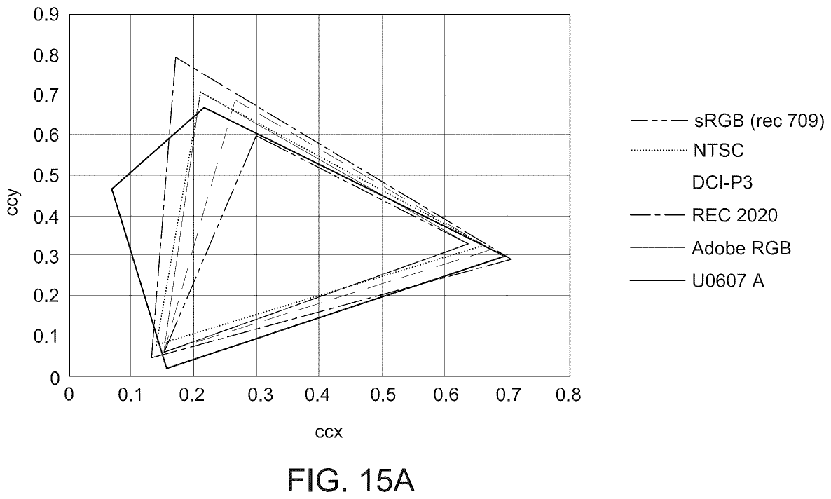

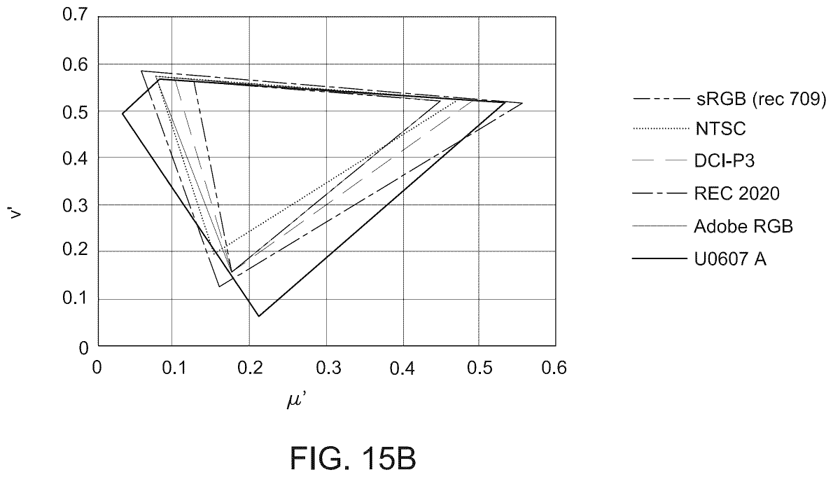

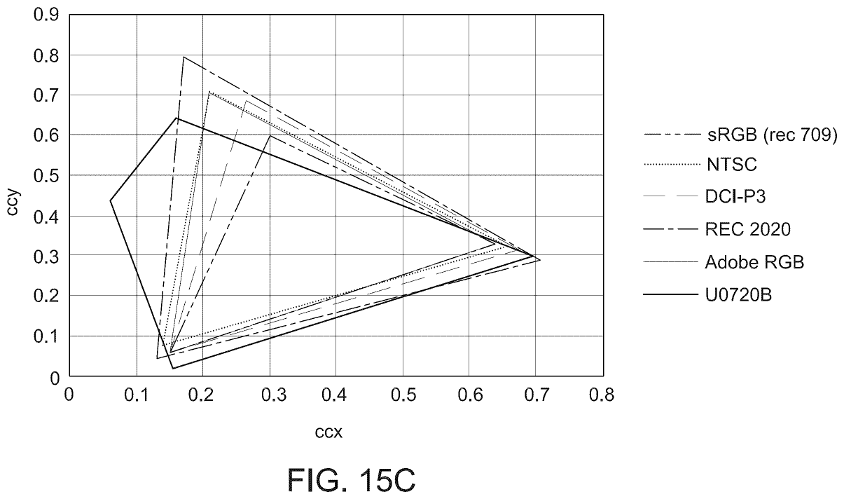

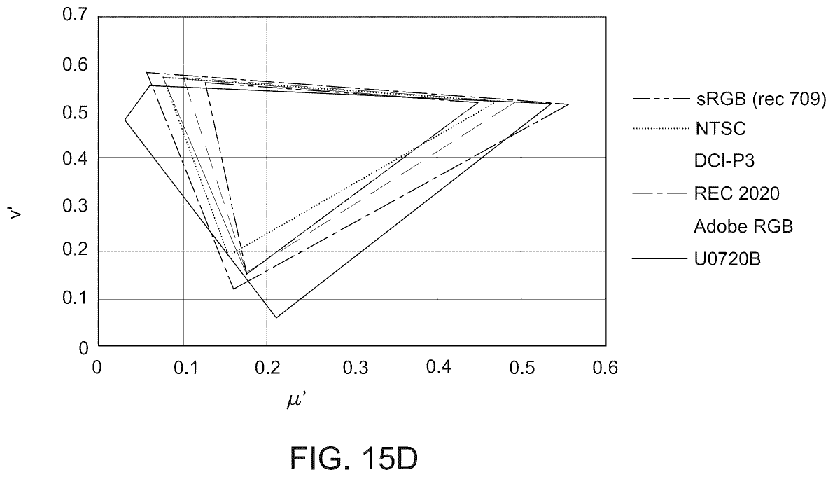

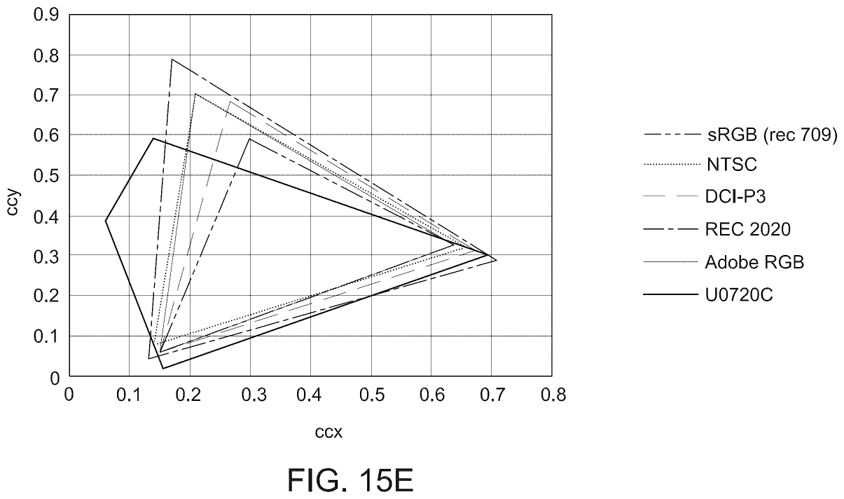

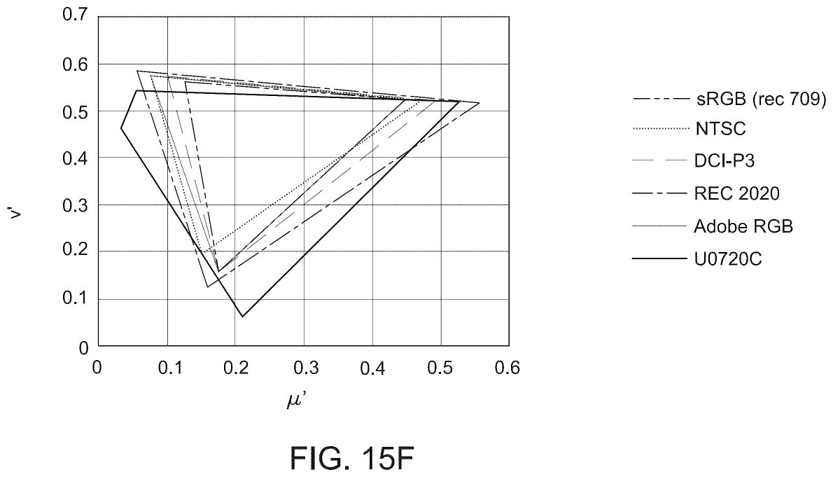

In one aspect, the color gamut coverage obtained by the four color RGBT filter and the four color RGGB filter can be varied by changing the host lattice of the U⁶⁺-containing phosphor and tuning the peak emission of the U⁶⁺-containing phosphor from about 505 nm to about 525 nm. FIG. 14 shows spectra for some exemplary U⁶⁺-phosphors (U0407B (BaZn₂(PO₄)₂):U⁶⁺, U0607A (K₃UO₂F₅), U0702B (K₂(UO₂)(SO₄)₂-2H₂O) and U0720C (Cs₂(UO₂)₂(SO₄)₃) having a peak emission from about 505 nm to about 525 nm. The ability to vary the color gamut coverage allows the color display to cover different color spaces. FIGS. 15A and 15B provide color spaces in (ccx, ccy), FIG. 15A, and (u′,v′), FIG. 15B, for exemplary sample U0607A. FIGS. 15C and 15D provide color spaces in (ccx, ccy), FIG. 15C, and (u′,v′), FIG. 15D, for exemplary sample U0720B. FIGS. 15E and 15F provide color spaces in (ccx, ccy), FIG. 15E, and (u′,v′), FIG. 15F, for exemplary sample U0720C. FIGS. 15A-15F show varying color gamut coverage by changing the host lattice for three color gamuts (U0607A, U0720B and U0720C) obtained by using the RGBT four color filter.

K₂UO₂(SO₄)₂-4H₂O preparation. K₂SO₄, UO₂(NO₃)₂-6H₂O was dissolved in a minimal amount of water in a ratio of 2:1. Once dissolved the K₂UO₂(SO₄)₂-4H₂O was formed by (salting out) adding ethanol to the solution. The product was filtered, washed with ethanol and then dried at 110° C. in a drying oven.

Cs₂UO₂(SO₄)₃ preparation. Cs₂SO₄, UO₂(NO₃)₂-6H₂O was dissolved in a minimal amount of water in a ratio of 2:1. Once dissolved the Cs₂UO₂(SO₄)₃ was formed by (salting out) adding ethanol to the solution. The product was filtered, washed with ethanol and then dried at 110° C. in a drying oven.

### Example 5

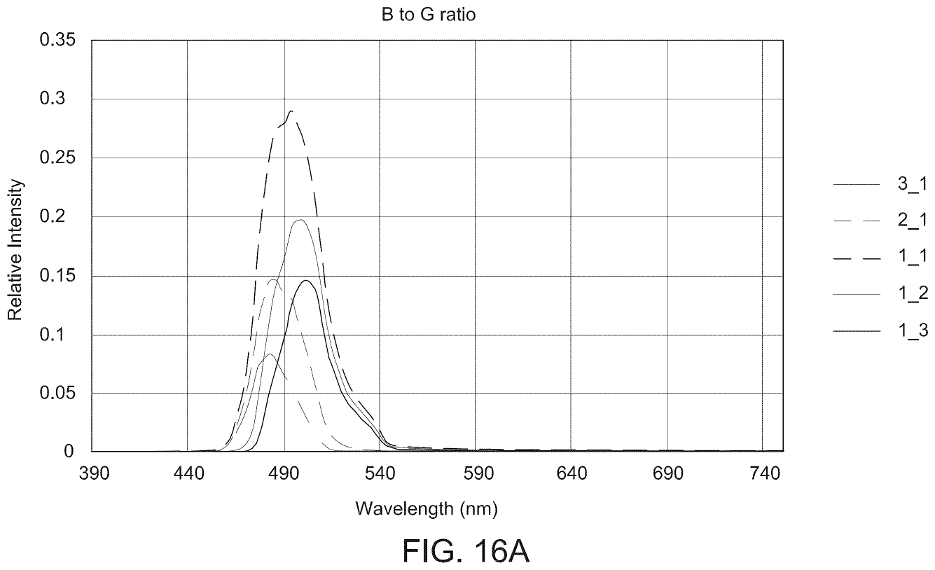

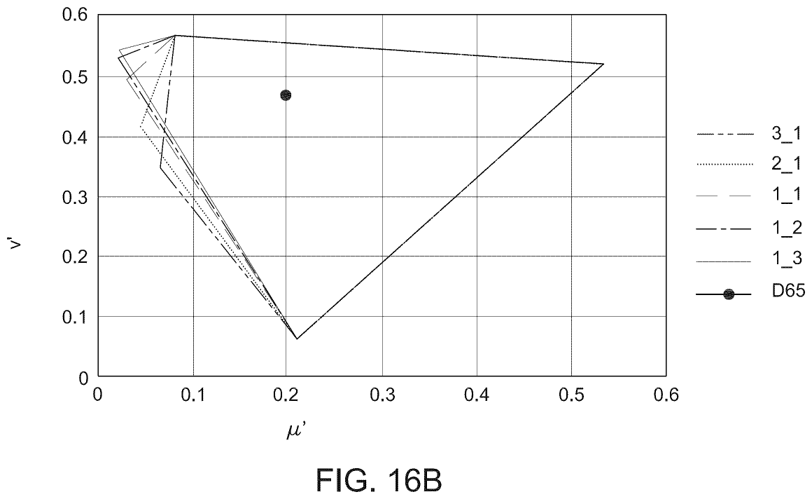

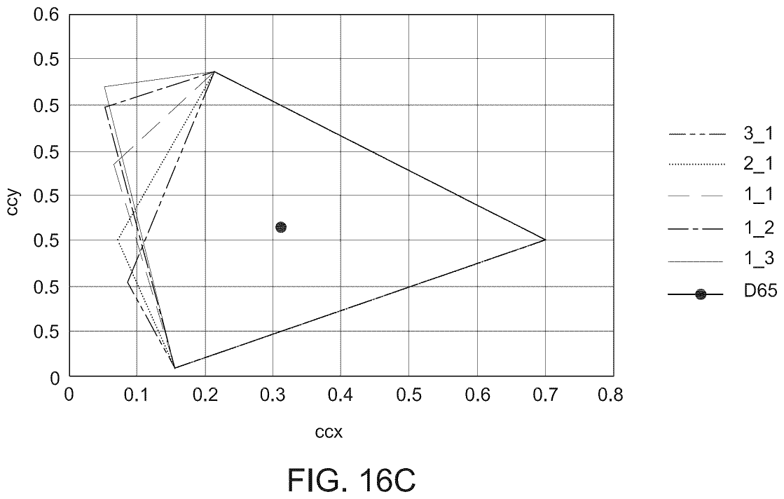

In one aspect, the color point of the teal subpixel obtained by the four color RGBT filter can be changed by varying the blue to green ratio in the teal color filter. FIG. 16A shows a teal filter having varying blue to green ratios of 1:3, 1:2, 1:1, 2:1 and 3:1 and the color space obtained in (u′,v′), FIG. 16B, and in (ccx,ccy), FIG. 16C, using the teal pixel filters with the varying blue to green ratios. As is shown, some of the ratios have a tie line drawn between the teal color point and the red color point of the color gamut that is below the D65 white point. Where a tie line between the teal color point and the red color point falls below the D65 point, then most of the colors in the color space can be generated with the red subpixel, green subpixel and teal subpixel without the use of the blue subpixel. As the teal color filter transmits light at wavelengths within the range of about 460 nm to about 550 nm, the teal subpixel does not include blue wavelengths within the range of about 460 nm to about 550 nm, the teal subpixel does not include blue wavelengths in the range of 415 nm to 455 nm, which are considered to be unsafe for human eyes. Activating the teal subpixel instead of the blue subpixel to produce the color display reduces hazardous blue light emissions from the display.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A display comprising a red subpixel, a green subpixel, a blue subpixel and a fourth subpixel comprising a teal subpixel or a saturated green subpixel and an LED light source.

2. The display according to claim 1, wherein the display is a liquid crystal display and the display further comprises a liquid crystal display panel and the LED light source comprises one or more LED backlight units, wherein the one or more LED backlight units comprise a combination of a blue LED optically coupled to a U⁶⁺-containing phosphor and a red phosphor.

3. The display according to claim 2, wherein the U⁶⁺-containing phosphor and the red phosphor are disposed on at least a portion of the blue LED or located remotely from the blue LED.

4. The display according to claim 3, wherein the green U⁶⁺-containing phosphor and the red phosphor are in the form of a film.

5. The display according to claim 4, wherein the blue LED is a miniLED.

6. The display according to claim 2, wherein the U⁶⁺-containing phosphor has a peak line emission at a wavelength range from about 470 nm to about 505 nm with a full width at half maximum of not more than 5 nm or a peak line emission at a wavelength range from about 505 nm to about 525 nm and a full width at half maximum of not more than 5 nm.

7. The display according to claim 2, wherein the U⁶⁺-containing phosphor is selected from the group consisting of: BaZn²(PO₄)²:U⁶⁺, BaBPO₅:U⁶⁺, K₃UO₂F₅, K₂(UO₂)(SO₄)₂-2H₂O, Cs₂(UO₂)₂(SO₄)₃, BaZnUO₂(PO₄)₂, BaMgUO₂(PO₄)₂, Ba₃(PO₄)₂(UO₂)₂P₂O₇ and Sr₃P₄O₁₃:U⁶⁺.

8. The display according to claim 2, wherein the red phosphor comprises a Mn⁴⁺-doped complex fluoride.

9. The display according to claim 2, wherein the red phosphor has formula I: A₂(MF₆):Mn⁴⁺, wherein A is Li, Na, K, Rb, Cs or a combination thereof; M is Si, Ge, Sn, Ti, Zr, Al, Ga, In, Sc, Hf, Y, La, Nb, Ta, Bi, Gd, or a combination thereof.

10. The display according to claim 2, wherein the red phosphor is selected from the group consisting of: K₂(SiF₆):Mn⁴⁺, K₂(TiF₆):Mn⁴⁺, K₂(SnF₆):Mn⁴⁺, Cs₂(TiF₆):Mn⁴⁺, Rb₂(TiF₆):Mn⁴⁺, Cs₂(SiF₆):Mn⁴⁺, Rb₂(SiF₆):Mn⁴⁺, Na₂(SiF₆):Mn⁴⁺, Na₂(TiF₆):Mn⁴⁺, Na₂(ZrF₆):Mn⁴⁺, K₃(ZrF₇):Mn⁴⁺, K₃(BiF₆):Mn⁴⁺, K₃(YF₆):Mn⁴⁺, K₃(LaF₆):Mn⁴⁺, K₃(GdF₆):Mn⁴⁺, K₃(NbF₇):Mn⁴⁺, and K₃(TaF₇):Mn⁴⁺.

11. The display according to claim 1, wherein the fourth subpixel comprises a teal subpixel and the U⁶⁺-containing phosphor has a line emission at a wavelength range from about 470 nm to about 505 nm with a full width at half maximum of not more than 5 nm.

12. The display according to claim 1, wherein the fourth subpixel comprises a saturated green pixel and the U⁶⁺-containing phosphor has a line emission at a wavelength range from about 505 nm to about 525 nm with a full width at half maximum of not more than 5 nm.

13. A display device for producing a color image, the display device comprising an LED backlight unit, a liquid crystal display panel and a pixel comprising a red subpixel, a green subpixel, a blue subpixel and a teal subpixel or a saturated green subpixel, wherein the LED backlight unit emits a white light and comprises a combination of a blue LED optically coupled to a U⁶⁺-containing phosphor and a red phosphor.

14. The display device according to claim 13, wherein the pixel comprises a teal subpixel and the LCD panel comprises a four color filter comprising a red filter, a green filter, a blue filter and a teal filter, to split the white light from the LED backlight unit into a red color point, a green color point, a blue color point and a teal color point, respectively, the four color points defining a color space of the display, the color space having a D65 white point and wherein a tie line between the teal color point and the red color point is below the D65 white point, wherein the U⁶⁺-containing phosphor has a line emission in the wavelength of about 470 nm to about 505 nm and a full width at half maximum of no more than 5 nm.

15. The display device according to claim 13, wherein the red phosphor comprises quantum dots materials.

16. The display device according to claim 13, wherein the teal subpixel comprises cyan, turquoise, electric blue, aquamarine, and other blue-green colors, and is produced by applying a teal color filter having an emission in the range of from about 460 nm to about 550 nm to the white light from the LED backlight unit.

17. The display device according to claim 13, wherein the saturated green subpixel is produced by applying a saturated green color filter having an emission in the range of from about 505 nm to about 525 nm.

18. A television comprising the display device of claim 13.

19. A mobile phone comprising the display device of claim 13.

20. A computer monitor comprising the display device of claim 13.
